(19) United States
(12) Patent Application Publication
(10) Pub. No.: US 2021/0359032 A1
(43) Pub. Date: Nov. 18, 2021

(54) DISPLAY SUBSTRATE AND MANUFACTURING METHOD THEREOF, DISPLAY PANEL AND DISPLAY DEVICE

(71) Applicants: ORDOS YUANSHENG OPTOELECTRONICS CO., LTD., Ordos, Inner Mongolia (CN); BOE TECHNOLOGY GROUP CO., LTD., Beijing (CN)

(72) Inventors: Yanqing CHEN, Beijing (CN); Jianyun XIE, Beijing (CN); Wei LI, Beijing (CN); Cheng LI, Beijing (CN); Pan GUO, Beijing (CN); Ning WANG, Beijing (CN)

(73) Assignees: ORDOS YUANSHENG OPTOELECTRONICS CO., LTD., Ordos, Inner Mongolia (CN); BOE TECHNOLOGY GROUP CO., LTD., Beijing (CN)

(21) Appl. No.: 16/612,224

(22) PCT Filed: May 9, 2019
(86) PCT No.: PCT/CN2019/086136

§ 371 Date: Nov. 8, 2019

(30) Foreign Application Priority Data
May 17, 2018 (CN) 201810473090.4

(51) Int. Cl. H01L 27/32; H01L 51/52; H01L 51/56

(52) U.S. Cl. CPC H01L 27/3218; H01L 51/5284; H01L 2227/323; H01L 51/56; H01L 27/322

(57) ABSTRACT

A display substrate and a manufacturing method thereof, a display panel and a display device are provided. The display substrate includes a display area having a curved boundary, and a plurality of pixel units located in the display area, the plurality of the pixel units include a plurality of first pixel units covering the curved boundary and second pixel units besides the first pixel units, a transmittance of the first pixel units is smaller than that of the second pixel units.

### CROSS-REFERENCE TO RELATED APPLICATION

This application claims a priority to Chinese Patent Application No. 201810473090.4 filed in China on May 17, 2018, the disclosure of which is incorporated herein in its entirety by reference.

### TECHNICAL FIELD

The present disclosure relates to a field of display technologies, in particular to a display substrate and a manufacturing method thereof, a display panel and a display device.

### BACKGROUND

With continuous development of display technology, full-screen display devices and smart wearable display devices are becoming popular. When a boundary of a display area is formed with arc or rounded corner, pixels located at the boundary of a display device are divided into two parts, i.e., a part inside the boundary and a part outside the boundary. During actual display procedure, it is determined, for each pixel at the boundary, whether an area of the part inside the boundary is larger than or equal to 50% of a total area of the pixel. If the area of the part inside the boundary of the pixel is larger than or equal to 50% of the total area of the pixel, the pixel is capable of emitting light. Otherwise, the pixel is totally shielded by a black matrix. For a display in the related art in which the pixel units are typically set to be rectangular, this dichotomy may cause a feeling of granularity and zigzag at the arc boundary when a user viewing a screen displayed by the display device.

### SUMMARY

In a first aspect, the present disclosure provides a display substrate, including: a plurality of pixel units, a display area of the display substrate including a linear boundary and a curved boundary, the plurality of the pixel units including a plurality of first pixel units covering the curved boundary and second pixel units besides the first pixel units, wherein each of the plurality of first pixel units is divided into an internal part of display area and an external part of display area by the curved boundary, a transmittance of each of the plurality of first pixel unit is proportional to an area of the internal part of display area.

Further, a ratio of the transmittance of any one of the plurality of first pixel units to a transmittance of a second pixel unit is equal to a ratio of the area of the internal part of display area of the first pixel unit to a total area.

Optionally, the plurality of the pixel units have a same rectangular shape and an equal area.

Optionally, the first pixel unit comprises at least two sub-pixels, each of the sub-pixels includes a light-shielding pattern and at least one light-transmitting region defined by the light-shielding pattern.

Optionally, a total area of all the light-transmitting regions in the first pixel unit is equal to the area of the internal part of display area of the first pixel unit.

Optionally, in each first pixel unit, an area of the light-transmitting region corresponding to each sub-pixel is equal.

Optionally, the sub-pixel comprises at least two light-transmitting regions arranged at intervals in a length direction of the sub-pixel.

Optionally, the light-shielding pattern is a black matrix pattern, a source-drain metal pattern or a gate metal pattern of the display substrate.

Optionally, the display substrate includes an array substrate on which the light-shielding pattern is formed and a color filter substrate.

Optionally, the display substrate is an Organic Light Emitting Diode (OLED) display substrate.

Based on the technical solution of the display substrate described above, in a second aspect, the present disclosure provides a method for manufacturing a display substrate, the display substrate includes a plurality of pixel units, a display area of the display substrate includes a linear boundary and a curved boundary, the method including: manufacturing a plurality of first pixel units covering the curved boundary and second pixel units besides the first pixel units, wherein each of the plurality of first pixel unit is divided into an internal part of display area and an external part of display area by the curved boundary, a transmittance of each of the plurality of first pixel units is proportional to an area of the internal part of display area.

Based on the technical solution of the display substrate described above, in a third aspect, the present disclosure provides a display panel including the display substrate described above.

Based on the technical solution of the display substrate described above, in a fourth aspect, the present disclosure provides a display device including the display panel described above.

### BRIEF DESCRIPTION OF THE DRAWINGS

The accompanying drawings described herein are provided for further understanding of the present disclosure and form a part of the present disclosure. The illustrative embodiments of the present disclosure and explanations thereof are used for interpreting the present disclosure merely and do not constitute improper limitations to the present disclosure.

FIG. 1 is a schematic diagram illustrating a structure of a display substrate according to the embodiments of the present disclosure;

FIG. 2 is a schematic diagram illustrating a structure of a first pixel unit of a display substrate according to the embodiments of the present disclosure;

FIG. 3 is a schematic diagram illustrating another structure of a first pixel unit of a display substrate according to the embodiments of the present disclosure.

### DETAILED DESCRIPTION

In order to further explain the display substrate and the manufacturing method thereof, the display panel and the display device in the embodiments of the present disclosure, the present disclosure will be illustrated in detail hereinafter with reference to the accompanying drawings.

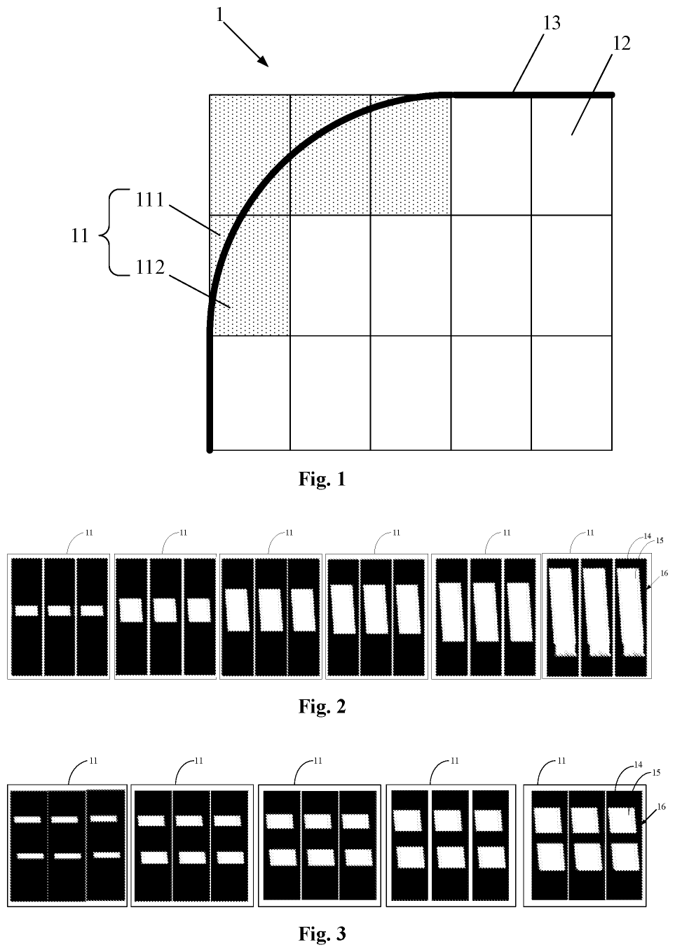

Referring to FIG. 1, the embodiments of the present disclosure provides a display substrate 1, including: a plurality of pixel units, a display area of the display substrate including a linear boundary and a curved boundary 13, the plurality of the pixel units including a plurality of first pixel units 11 covering the curved boundary and second pixel units 12 besides the first pixel units, wherein each first pixel unit 11 is divided into an internal part 112 of display area and an external part 111 of display area by the curved boundary 13, a transmittance of each first pixel unit 11 is proportional to an area of the internal part 112 of display area.

Specifically, as an illustrative introduction, the curved boundary 13 may include an arc-shaped boundary that does not match a shape of the pixel unit. It should be appreciated that, a right-angled boundary (such as the right angle formed by an intersection of two boundaries) may belong to or not belong to the curved boundary 13.

Since a pixel unit in the related art is usually rectangular, the first pixel unit 11 located near the curved boundary 13 covers the curved boundary 13 and is divided into the internal part 112 of display area (i.e., a part inside the display area) and the external part 111 of display area (i.e., a part outside the display area). Other than the first pixel units 11, all of the second pixel units 12 are located within the display area. During an actual display procedure of the display substrate 1, a display function is realized by the internal part 112 of display area of the first pixel unit 11 and the second pixel unit 12.

Each of the first pixel unit 11 is divided into the internal part 112 of display area and the external part 111 of display area by the curved boundary 13, and the transmittance of the first pixel unit 11 is proportional to the area of the internal part 112 of display area.

Specifically, the display substrate 1 may include the plurality of the first pixel units 11, wherein each first pixel unit 11 is divided into the internal part 112 of display area and the external part 111 of display area by the curved boundary 13, the area of the internal part 112 of display area corresponding to each first pixel unit 11 may be equal or different. By setting the transmittance of the first pixel unit 11 to be proportional to the area of the internal part 112 of display area (here the shape and area of each pixel unit are set to be the same), it is possible to make the first pixel unit 11 have a high transmittance when the first pixel unit 11 has a large effective display area, thereby enabling the first pixel unit 11 to have a high display brightness. And when the first pixel unit 11 has a small effective display area, the first pixel unit 11 has a small transmittance, so that the display brightness of such a first pixel unit 11 is low.

In the solution of the present disclosure, a pixel located at the curved boundary is set to render a low display gray level (brightness) if the pixel has a small area ratio within the display area, or render a high brightness if the pixel has a large area ratio within the display area, said “area ratio” referring to a ratio between an area within the display area of a pixel and a total area of the pixel. Because a size of the pixel unit is very small, the pixel provides only a “bright spot” in human eyes. The human eyes may only perceive merely a change of brightness for those pixels at the boundary region, especially in a curved boundary region. Since the gray levels of those “bright spot” at the boundaries form a smooth transition, a smooth rather than granular or zigzagged boundary can be perceived by the human eyes. With the above-mentioned settings of the present disclosure, for those first pixel units 11 of which the internal part of display area has a small area, a lower brightness is provided matching the small area falling within the curved boundary; similarly, for those first pixel units 11 of which the internal part of display area has a large area, a higher brightness is provided matching the large area falling within the curved boundary.

In other words, assuming that at the curved boundary, a part of the first pixel unit that falls within the curved boundary emits light while a part that falls outside the curved boundary does not emit light, which provides the user with an ideal view of the curved boundary. According to the technical solution of the present disclosure, on the premise that each pixel unit has a same rectangular structure and all pixel units emit light as a whole, a good visual sense of the curved boundary may be provided similar to the ideal case described above.

Therefore, an array substrate in the above embodiments may make the brightness of the first pixel unit 11 forms a soft transition near the curved boundary 13, and the “bright spot” gray levels at the boundary form a smooth transition, which enables the human eyes to perceive a smooth rather than granular or zigzagged boundary, thereby improving a viewing experience of the user.

A structure of the first pixel unit 11 in the above embodiment may varies, for example, the first pixel unit 11 includes at least two sub-pixels, the sub-pixel includes a light-shielding pattern and at least one light-transmitting region defined by the light-shielding pattern.

Specifically, as shown in FIG. 2, the first pixel unit 11 includes three sub-pixels 16 (e.g., a red sub-pixel, a green sub-pixel and a blue sub-pixel), each sub-pixel 16 includes a light-shielding pattern 14 and at least one light-transmitting region 15 defined by the light-shielding pattern.

The light-shielding pattern 14 may shield a part of the sub-pixel 16, so that the part shielded by the light-shielding pattern 14 in the sub-pixel 16 is opaque, and a part not shielded by the light-shielding pattern 14 forms the light-transmitting region 15 of the sub-pixel 16, and the light-transmitting region 15 is used for screen display.

In a practical application, in order to avoid an additional manufacturing process and a cost of the display substrate 1 in an implementation of the solution of the above-mentioned embodiment, the light-shielding pattern 14 may be at least one of a black matrix pattern, a source-drain metal pattern or a gate metal pattern of the display substrate 1, or the light-shielding pattern 14 may be manufactured with the black matrix pattern, the source-drain metal pattern and the gate metal pattern through a single patterning process.

Optionally, a total area of all the light-transmitting regions 15 in the first pixel unit 11 is equal to the area of the internal part 112 of display area of the first pixel unit 11 may be set.

Since the internal part 112 of display area of the first pixel unit 11 is an effective display area of the first pixel unit 11, it is possible to set a total area of all the light-transmitting regions 15 in the first pixel unit 11 to be equal to the area of the internal part 112 of display area of the first pixel unit 11, so that the transmittance of the first pixel unit 11 matches an area of the effective display area of the first pixel unit 11. That is, when the area of the effective display area of the first pixel unit 11 is large, the transmittance of the first pixel unit 11 is set to be large, and when the area of the effective display area of the first pixel unit 11 is small, the transmittance of the first pixel unit 11 is set to be small. Therefore, the zigzag sense near the curved boundary in the displayed screen may be alleviated and the display quality of the screen can be improved.

Optionally, in each first pixel unit 11, an area of the light-transmitting region 15 corresponding to each sub-pixel 16 is equal.

Specifically, by setting the area of the light-transmitting region 15 corresponding to each sub-pixel 16 in each first pixel unit 11 to be equal, each sub-pixel 16 has a same transmittance, which guarantees a color uniformity of the display screen of each first pixel unit 11, and further improves the display quality of the display substrate 1.

Each sub-pixel 16 of the display substrate 1 in the above embodiment may include one light-transmitting region 15 or at least two light-transmitting regions 15.

Referring to FIG. 2, taking each sub-pixel 16 including only one light-transmitting region 15 as an example, FIG. 2 shows six adjacent first pixel units 11, the sub-pixel of each first pixel unit 11 is shielded by the light-shielding pattern 14 to form the light-transmitting region 15.

Assuming that the area of the internal part 112 of display area of the first pixel unit 11 decreases gradually in an order from right to left in FIG. 2, it can be seen that the smaller the internal part 112 of display area of the first pixel unit 11 is, the smaller the area of light-transmitting region 15 corresponding to the first pixel unit 11 is, and a lower brightness is rendered in the display effect.

Optionally, the sub-pixel 16 includes at least two light-transmitting regions 15 arranged at intervals in a length direction of the sub-pixel 16.

Referring to FIG. 3, taking each sub-pixel 16 including at least two light-transmitting regions 15 as an example, for each sub-pixel 16, at least two light-transmitting regions 15 are arranged at intervals in the length direction of sub-pixel 16 (the length direction refers to an extension direction of a long side of the sub-pixel 16). Compared with the sub-pixel 16 shown in FIG. 2, the sub-pixel 16 in FIG. 3 has more light-transmitting regions 15, which makes a distribution of the light-transmitting regions between adjacent two sub-pixels 16 more uniform, makes the transition of brightness more soft, and further makes the “bright spot” gray levels at the boundary form a smooth transition, so that the human eye may perceive a smooth rather than granular or zigzagged boundary, thereby improving a viewing experience of the user.

The embodiments of the present disclosure further provide a method for manufacturing a display substrate, the display substrate includes a display area having a curved boundary 13, and a plurality of pixel units located in the display area, the method includes: manufacturing, a plurality of first pixel units 11 covering the curved boundary 13 and second pixel units 12 besides the first pixel units 11, a transmittance of each first pixel unit 11 is smaller than that of the second pixel unit 12.

The method of the embodiments of the present disclosure is provided for manufacturing the display substrate 1 in the above embodiment, technical effects achieved by the display substrate 1 can also be realized by the method of the present embodiments.

Optionally, in a practical application, the method in the above embodiment, a light-shielding pattern 14 may be set on an area of the sub-pixel 16 in the first pixel unit 11 to change a transmittance of the first pixel unit 11. Specifically, the first pixel unit 11 includes at least two sub-pixels 16, and the sub-pixel 16 includes the light-shielding pattern and at least one light-transmitting region defined by the light-shielding pattern. A ratio of the light-transmitting region 15 to the sub-pixel 16 determines a transmittance of the first pixel unit 11. That is, the larger the ratio of the light-transmitting region 15 to the sub-pixel 16 is, the larger the transmittance of the first pixel unit 11 is, and a higher display brightness is provided. Conversely, the smaller the ratio of the light-transmitting region 15 to the sub-pixel 16 is, the smaller the transmittance of the first pixel unit 11 is, and a lower display brightness is provided.

In the practical application, in order to avoid additional manufacturing process, other light shielding patterns on a conventional display substrate 1 may be used as the light-shielding pattern 14 of the embodiment, such as a black matrix pattern, a source-drain metal pattern or a gate metal pattern of the display substrate 1. Otherwise, the existing light shielding patterns on the conventional display substrate 1 and the light-shielding pattern 14 of the present embodiment may be formed through single patterning process. Therefore, the manufacturing process of the light-shielding pattern 14 is not particularly limited, which may be performed before or after manufacturing the pixel electrodes.

Taking the light-shielding pattern 14 and the source-drain metal pattern manufactured by single patterning process as an example, steps of manufacturing the light-shielding pattern 14 in the embodiment may be as follows.

Prior to a manufacturing process of the pixel electrodes, a source-drain metal layer made of Cu, Al, Ag, Mo, Cr, Nd, Ni, Mn, Ti, Ta, W or an alloy thereof, with a thickness of about 2000 Å-4000 Å, is deposited on a substrate of the display substrate 1 by magnetron sputtering, thermal evaporation or other film forming methods. The source-drain metal layer may be a single-layer or multi-layer structure such as Cu\Mo, Ti\Cu\Ti, Mo\Al\Mo, etc. A photoresist layer is coated on the source-drain metal layer, and exposed with a mask plate to form a photoresist removing region and a photoresist residual region. The photoresist residual region corresponds to an area where a source electrode, a drain electrode and the light-shielding pattern 14 are located, and the photoresist removing region corresponds to an area other than the above patterns. Then a developing process is performed, the photoresist removing region is removed completely, and a thickness of the photoresist residual region remains unchanged. The source-drain metal layer of the photoresist removing region is completely etched by an etching process, and the remaining photoresist is peeled off to form the drain electrode, the source electrode and the light-shielding pattern 14.

It should be appreciated that, the principle of manufacturing the light-shielding pattern 14 and other light-shielding patterns through a single etching process is the same as the above steps, the details of which are not repeated herein.

In addition, another embodiment of the present disclosure also provides a display panel including the display substrate 1 in the above embodiments.

According to the display substrate 1 of the embodiment, a smooth transition can be formed by the “bright spot” gray levels at the curved boundary, which enables human eyes to perceive a smooth rather than granular or zigzagged boundary, thereby improving a viewing experience of the user.

It should be appreciated that, the display panel in the embodiments of the present disclosure may be applied to any kind of display products, either a single substrate structure (e.g. Organic Light Emitting Diode (OLED) display products) or a double substrate structure formed by a cell aligning process (e.g. for Liquid Crystal Display (LCD) products). For LCD display devices, the display substrate includes an array substrate and a color filter substrate, and the light-shielding pattern may be formed on the array substrate. For OLED display products, the light-shielding pattern may be formed on OLED display substrates.

In addition, another embodiment of the present disclosure also provides a display device including the display panel in the above embodiment of the present disclosure. Therefore, the display device of the embodiment can also achieve the technical effect that the display panel achieves.

In a practical application, the display device in the embodiments of the present disclosure may be any product or component with display function, such as a liquid crystal television, a liquid crystal display, a digital photo frame, a mobile phone, a tablet computer, etc., especially a display product with a high screen proportion, such as a full screen display device and a smart wearable device. Since a display area of this kind of products occupies almost a whole display surface, a boundary of the display area matches a frame of the product, resulted in that the display area typically has curved boundaries (such as four rounded corners) and cannot match the rectangular pixel unit. According to the display device of the embodiment, a smooth transition can be formed by the “bright spot” gray levels at the curved boundary, which enables human eyes to perceive a smooth rather than granular or zigzagged boundary, thereby improving a display quality of screen, improving a viewing experience of the user. Therefore, the display device has a high value in use.

Unless defined otherwise, technical or scientific terms in the embodiments of the present disclosure shall be of general meanings understood by those skilled in the art. Terms “first”, “second” and similar terms in the embodiments of the present disclosure do not indicate any order, quantity or importance, but are used only for distinguishing different components. A term “include”, “comprise” or other term with similar meaning indicates that components or objects before the term cover components, objects or other equivalents listed after the term, instead of excluding other components or objects. A term “connect”, “attach” or other term with similar meaning is not limited to a physical connection or a mechanical connection, but may include an electrical connection, whether direct or indirect. “Up”, “down”, “left”, “right” and so on are only used to represent a relative position relationship. When an absolute position of an object is changed, the relative position relationship may also change accordingly.

It should be appreciated that, when a component such as a layer, film, region or substrate is said to be located “above” or “below” another component, the component may be “directly” located “above” or “below” another component, or intermediate components may exist.

In the description of the above embodiments, specific features, structures, materials or features may be combined in an appropriate manner in any one or more embodiments or examples.

The above are merely embodiments of the present disclosure, but a protection scope of the present disclosure is not limited thereto. It should be appreciated that a person skilled in the art may make further modifications and improvements without departing from the spirit of the present disclosure, and these modifications and improvements shall also fall within the scope of the present disclosure. Therefore, the protection scope of the present disclosure shall be subject to the protection scope of the claims.

1. A display substrate, comprising a plurality of pixel units, a display area of the display substrate comprising a linear boundary and a curved boundary, the plurality of the pixel units comprising a plurality of first pixel units covering the curved boundary and second pixel units besides the first pixel units, wherein each of the plurality of first pixel units is divided into an internal part of display area and an external part of display area by the curved boundary, a transmittance of each of the plurality of first pixel unit is proportional to an area of the internal part of display area.

2. The display substrate according to claim 1, wherein a ratio of the transmittance of any one of the plurality of first pixel units to a transmittance of a second pixel unit is equal to a ratio of the area of the internal part of display area of the first pixel unit to a total area.

3. The display substrate according to claim 1, wherein the plurality of the pixel units have a same rectangular shape and an equal area.

4. The display substrate according to claim 1, wherein the first pixel unit comprises at least two sub-pixels, each sub-pixel comprises a light-shielding pattern and at least one light-transmitting region defined by the light-shielding pattern.

5. The display substrate according to claim 4, wherein a total area of all the light-transmitting regions in the first pixel unit is equal to the area of the internal part of display area of the first pixel unit.

6. The display substrate according to claim 4, wherein in each first pixel unit, an area of the light-transmitting region corresponding to each sub-pixel is equal.

7. The display substrate according to claim 4, wherein the sub-pixel comprises at least two light-transmitting regions arranged at intervals in a length direction of the sub-pixel.

8. The display substrate according to claim 4, wherein the light-shielding pattern is a black matrix pattern or a source-drain metal pattern or a gate metal pattern of the display substrate.

9. The display substrate according to claim 8, comprising an array substrate on which the light-shielding pattern is formed and a color filter substrate.

10. The display substrate according to claim 8, wherein the display substrate is an Organic Light Emitting Diode (OLED) display substrate.

11. A method for manufacturing a display substrate, wherein the display substrate comprises a plurality of pixel units, a display area of the display substrate comprises a linear boundary and a curved boundary, the method comprising:
manufacturing a plurality of first pixel units covering the curved boundary and second pixel units besides the first pixel units, wherein each of the plurality of first pixel units is divided into an internal part of display area and an external part of display area by the curved boundary, a transmittance of each of the plurality of first pixel units is proportional to an area of the internal part of display area.

12. A display panel, comprising the display substrate according to claim 1.

13. A display device, comprising the display panel according to claim 12.

14. The display substrate according to claim 2, wherein the first pixel unit comprises at least two sub-pixels, each sub-pixel comprises a light-shielding pattern and at least one light-transmitting region defined by the light-shielding pattern.

15. The display substrate according to claim 3, wherein the first pixel unit comprises at least two sub-pixels, each sub-pixel comprises a light-shielding pattern and at least one light-transmitting region defined by the light-shielding pattern.
